(19) United States
(12) Patent Application Publication
(10) Pub. No.: US 2026/0365208 A1
(43) Pub. Date: Nov. 19, 2026

(54) Transport Facility

(71) Applicant: Daifuku Co., Ltd., Osaka-shi (JP)

(72) Inventors: Shota Ito, Komaki-shi (JP); Makoto Kono, Komaki-shi (JP)

(21) Appl. No.: 19/680,734

(22) Filed: May 18, 2026

(30) Foreign Application Priority Data
May 19, 2025 (JP) 2025-083156

(51) Int. Cl. B61L 27/16; H10P 72/30

(52) U.S. Cl. CPC B61L 27/16; H10P 72/3214; H10P 72/3216

(57) ABSTRACT

A transport facility includes a section control system. The section control system executes occupancy processing for occupying a passing point for a transport vehicle that is about to pass through a specific section, and occupancy cancellation processing for canceling the occupancy for another transport vehicle that is about to pass through the specific section. The specific section includes a cancellation point that is set upstream of the passing point subjected to occupancy and is variable in accordance with a predetermined condition. The occupancy cancellation processing is for canceling the occupancy of the passing point if the transport vehicle that has been granted the passing permission for the passing point is located at the cancellation point set upstream of the passing point. The cancellation point is set such that the separation distance from the passing point becomes longer as the travel speed of the transport vehicle granted the passing permission increases.

### CROSS-REFERENCE TO RELATED APPLICATION

This application claims priority to Japanese Patent Application No. 2025-083156 filed May 19, 2025, the disclosure of which is hereby incorporated by reference in its entirety.

### BACKGROUND OF THE INVENTION

### 1. Field of the Invention

The present invention relates to a transport facility that includes a transport vehicle, a travel path along which the transport vehicle is travelable, and a section control system configured to issue a passing permission and a stop command to the transport vehicle traveling in a specific section set on the travel path to control the transport vehicle.

### 2. Description of Related Art

JP 2006-313463A discloses an example of this type of article transport facility as a transport carriage system. In the following description of the related art, the reference numerals in parentheses are those of JP 2006-313463A.

In the system disclosed in JP 2006-313463A, a lock point is provided in a branching area or a merging area of a travel path for a transport vehicle (5). A section in which such a lock point is provided (hereinafter referred to as a “specific section”) is used as a unit to determine whether or not to permit the transport vehicle (5) to pass the lock point.

Before entering the specific section where the lock point is provided, the transport vehicle (5) makes a blocking request to a zone controller (11) to request that other transport vehicles (5) be prevented from entering the specific section. In the case where the zone controller (11) permits the transport vehicle (5) that has made the blocking request to pass through the specific section, the zone controller (11) issues a blocking permission and prevents other transport vehicles (5) from passing. After the transport vehicle (5) has passed, the zone controller (11) cancels the blocking in the specific section and becomes ready to accept other transport vehicles (5). According to this type of system, it is possible to prevent a following transport vehicle from colliding with a preceding transport vehicle in the specific section.

However, in the system disclosed in JP 2006-313463A, the following transport vehicle is forced to wait until the preceding transport vehicle exits the specific section and the blocking is canceled. The waiting time of the transport vehicle becomes idle time in which the transport of articles is stopped, which may reduce the transport efficiency of the entire facility.

### SUMMARY OF THE INVENTION

In view of the foregoing situation, it is desirable to facilitate the movement of the following transport vehicle in the specific section and to improve the transport efficiency of the entire facility.

The following is a technology for solving the above problems.

A transport facility includes:
a transport vehicle;
a travel path along which the transport vehicle is travelable; and
a section control system configured to issue a passing permission and a stop command to the transport vehicle traveling in a specific section set on the travel path to control the transport vehicle,
the specific section including at least one stopping point set at an entrance thereof, wherein the transport vehicle is configured to stop at the stopping point in response to the stop command,
the specific section including at least one passing point set at an exit thereof, wherein the transport vehicle that has been granted the passing permission is configured to pass the passing point,
the section control system being configured to execute: (i) occupancy processing for occupying the passing point for the transport vehicle that is about to pass through the specific section; and (ii) occupancy cancellation processing for canceling the occupancy for another transport vehicle that is about to pass through the specific section,
the specific section including a cancellation point that is set upstream of the passing point subjected to occupancy and that is variable in accordance with a predetermined condition,
the occupancy cancellation processing being processing for canceling the occupancy of the passing point if the transport vehicle that has been granted the passing permission for the passing point is located at the cancellation point set upstream of the passing point, and
the cancellation point being set in such a manner that a separation distance from the passing point becomes longer as a travel speed of the transport vehicle that has been granted the passing permission increases.

According to this configuration, the occupancy of the passing point that has been occupied for a preceding transport vehicle can be canceled earlier for a following transport vehicle. This makes it possible to shorten the waiting time of the following transport vehicle at the stopping point, allowing the following transport vehicle to enter the specific section earlier. In addition, the cancellation point serving as a trigger for occupancy cancellation is set in accordance with the travel speed of the transport vehicle. Since the braking distance of the transport vehicle becomes longer as the travel speed increases, this configuration can make it difficult for the preceding transport vehicle to stop before reaching the passing point, even if the preceding transport vehicle begins a stopping operation after passing the cancellation point. Therefore, it is possible to reduce the likelihood that the following transport vehicle that has been granted a passing permission for the passing point will stop in the specific section in order to avoid a collision with the stopped preceding transport vehicle. As described above, according to this configuration, the movement of the transport vehicles in the specific section can be facilitated, and the transport efficiency of the entire facility can be improved.

Further features and advantages of the technology according to the present disclosure will become more apparent through the following description of a non-limiting illustrative embodiment with reference to the drawings.

### BRIEF DESCRIPTION OF THE DRAWINGS

FIG. 1 is a plan view of a transport facility.

FIGS. 2A and 2B illustrate occupancy cancellation processing in a comparative example.

FIG. 3 shows a processing procedure of a section control system in the comparative example.

FIG. 4 illustrates occupancy cancellation processing in the present embodiment.

FIG. 5 shows a processing procedure of a section control system in the present embodiment.

FIGS. 6A and 6B illustrate setting of a cancellation point.

FIG. 7 illustrates occupancy cancellation processing in a case where a specific section includes a branching area and a merging area.

FIG. 8 illustrates occupancy cancellation processing in a case where a specific section includes a branching area and a merging area.

### DESCRIPTION OF THE INVENTION

An embodiment of a transport facility will be described below with reference to the drawings.

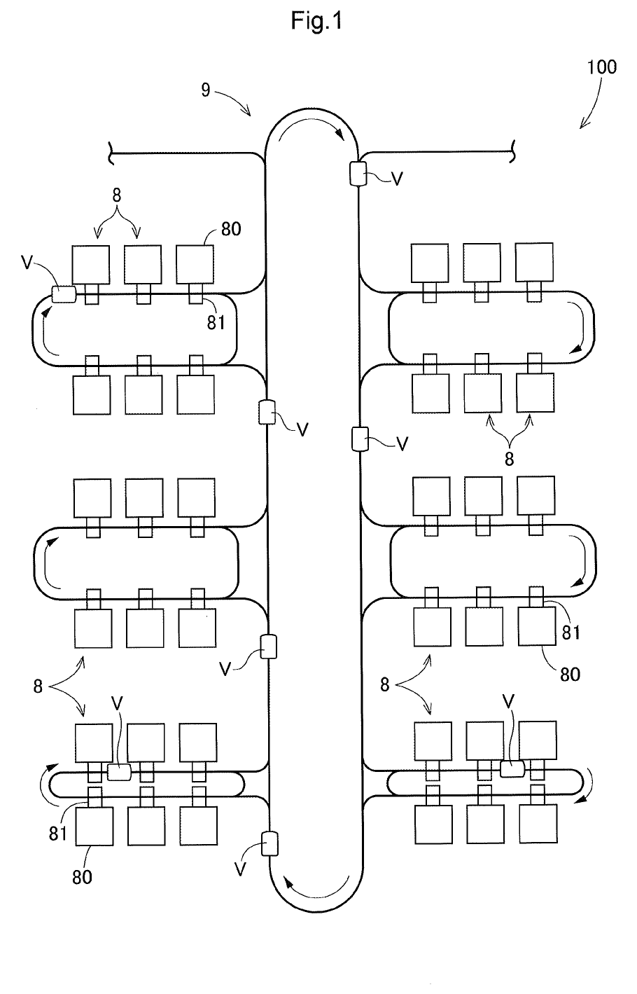

As shown in FIG. 1, a transport facility 100 includes transport vehicles V and a travel path 9 along which the transport vehicles V travel. Examples of the transport vehicles V include so‑called overhead hoist transport vehicles that travel along travel rails installed near a ceiling.

In the present embodiment, a plurality of transfer target locations 8 are provided along the travel path 9. Each of the transport vehicles V is configured to execute tasks assigned thereto and, for example, transports an article (not shown) to a transfer target location 8.

The transport facility 100 is used, for example, in a semiconductor manufacturing plant. In this case, a processing device 80 that performs processing on an article may be an example of each of the transfer target locations 8. Also, a front opening unified pod (FOUP) for housing wafers or a reticle pod for housing a reticle may be an example of the article. If the article is a FOUP, the processing target object for the processing device 80 is a wafer. If the article is a reticle pod, the processing target object for the processing device 80 is a reticle. In the semiconductor manufacturing plant illustrated herein, the processing device 80 performs various types of processing such as thin‑film formation, photolithography, and etching on a semiconductor substrate. The processing device 80 is configured to take the processing target object out of articles on a placing table 81 disposed adjacent to the processing device 80, and to perform processing on this processing target object. The articles are transferred to and from the placing table 81 by the transport vehicle V.

The travel path 9 includes a branching area 91 where one path branches into a plurality of paths, and a merging area 92 where a plurality of paths merge into one path. In the present embodiment, the travel path 9 is a one‑way path, and the transport vehicle V cannot travel in the reverse direction along the travel path 9. Therefore, in the branching area 91, the transport vehicle V selects one of the branched paths and travels along the selected path. In the merging area 92, regardless of which of the paths the transport vehicle V is traveling along, the transport vehicle V will travel along a single path after passing through the merging area (there is no option for path selection). Therefore, if a plurality of transport vehicles V enter the merging area 92 simultaneously from different paths, only one of the transport vehicles V is permitted to pass, and the other transport vehicles V needs to be prevented from passing.

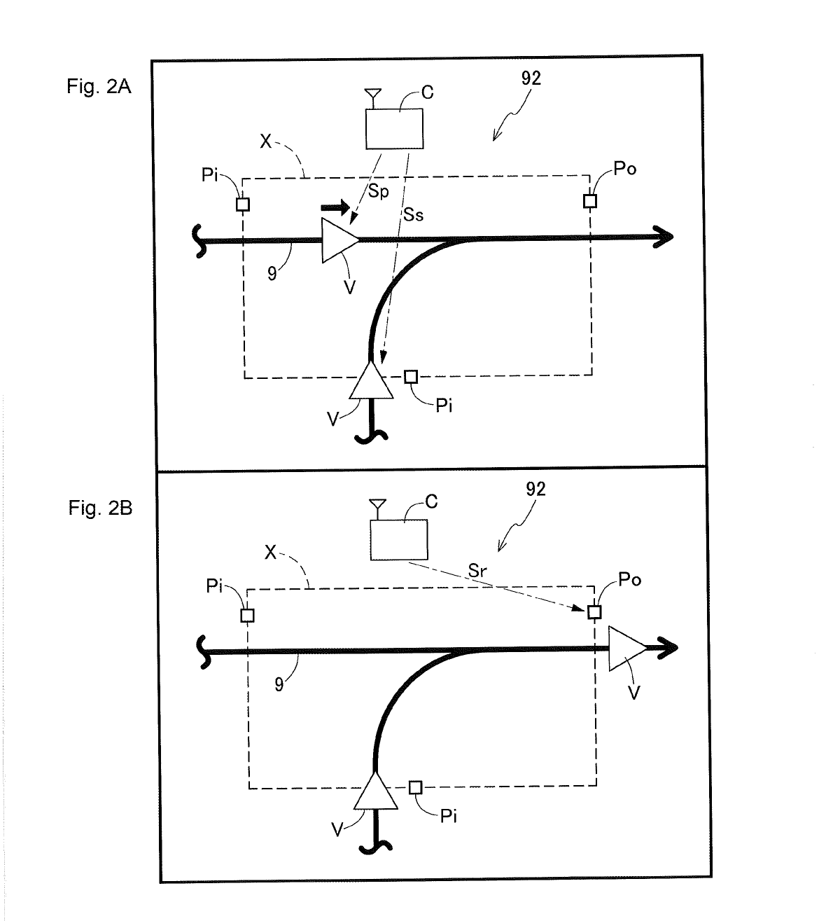

Thus, a specific section X (see FIGS. 2A and 2B) that includes at least the merging area 92 is set on the travel path 9, and only the transport vehicle V that has been permitted to pass can travel in this specific section X.

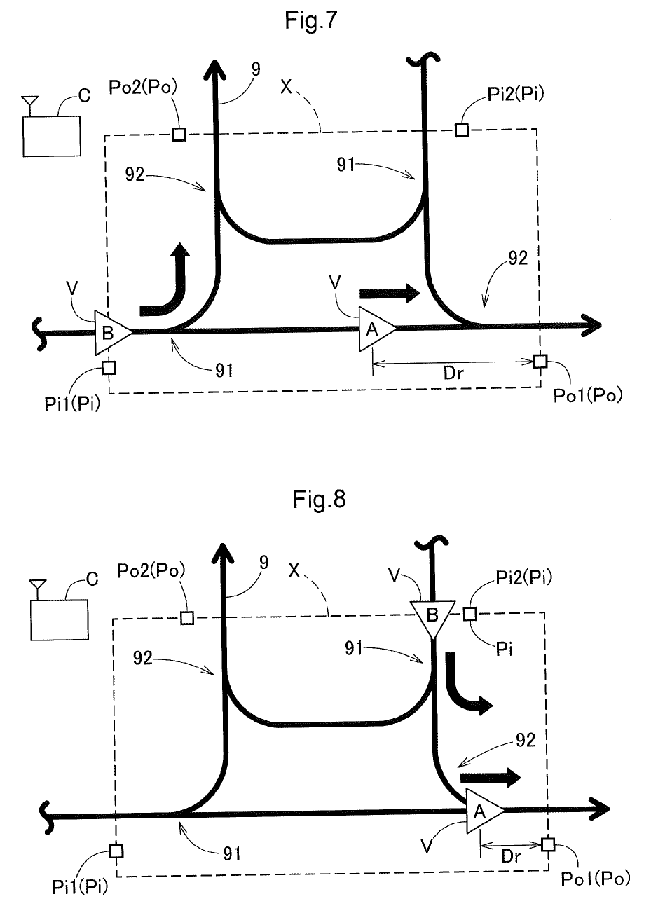

As shown in FIGS. 2A and 2B, the transport facility 100 includes a section control system C that issues a passing permission Sp and a stop command Ss to the transport vehicle V traveling in the specific section X set on the travel path 9 to control the transport vehicle V. In the example shown in FIGS. 2A and 2B, the specific section X includes a single merging area 92. However, the specific section X may also include a branching area 91. Furthermore, the specific section X may include more than one branching area 91 and more than one merging area 92 (see FIGS. 7 and 8).

The section control system C is, for example, a zone controller (or a program) that performs only traffic management for the specific section X. Note that the section control system C may also include a host controller that centrally manages the transport facility 100, a transport vehicle controller mounted on the transport vehicle V, and the like.

In this example, the section control system C communicates with the transport vehicle V to control the transport vehicle V. Communication is performed wirelessly, but wired communication may also be used for at least a portion of the communication path. The section control system C is configured to acquire transport vehicle information from each of the plurality of transport vehicles V. In this example, the transport vehicle information includes identification information for identifying an individual transport vehicle V, current position information of the transport vehicle V, travel speed information of the transport vehicle V, weight information of the transport vehicle V, article presence information indicating whether the transport vehicle V is holding an article, and wear level information of wheels of the transport vehicle V. The section control system C uses such transport vehicle information to control the transport vehicle V. Details thereof will be described later.

The section control system C includes, for example, a processor such as a microcomputer, a peripheral circuit such as a memory, and the like. Each type of processing or each function is implemented by cooperation between these pieces of hardware and a program executed on a processor such as a computer.

The section control system C is configured to control the timing of each of the plurality of transport vehicles V entering the specific section X such that the transport vehicles V can pass through the specific section X in sequence without interfering with each other.

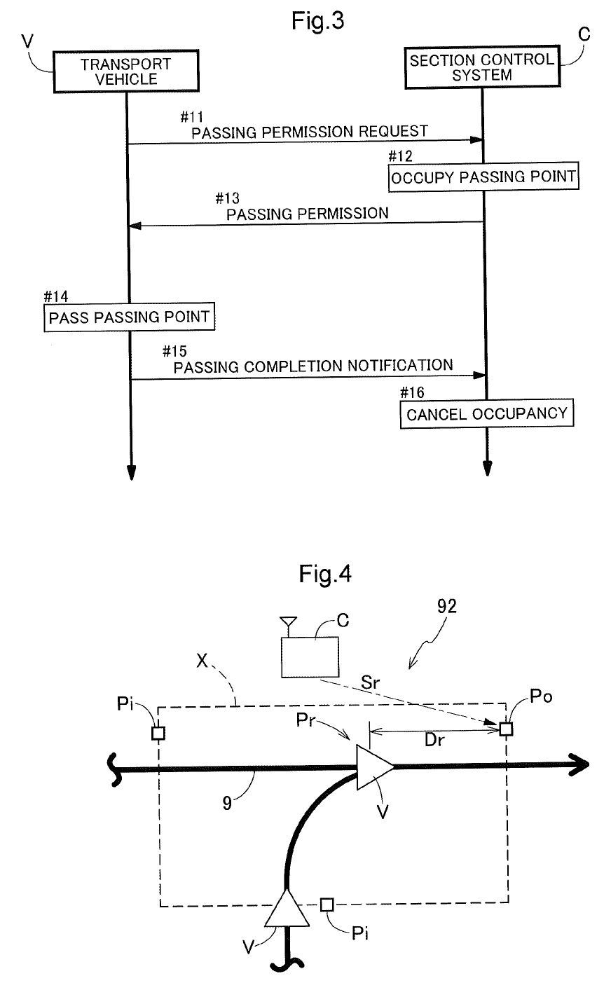

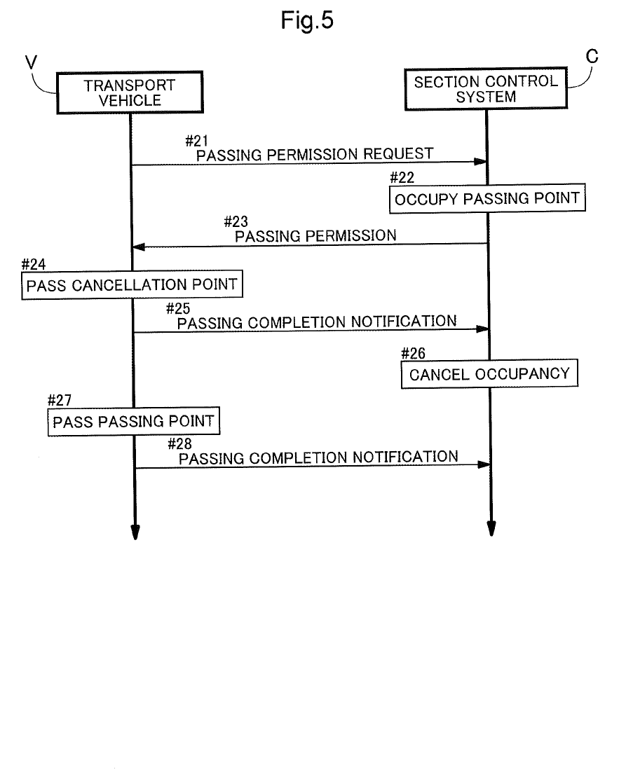

FIGS. 2A and 2B and 3 illustrate a comparative example of the control in the specific section X, and FIGS. 4 and 5 illustrate the content of the control according to the present disclosure.

As shown in FIGS. 2A and 2B, a stopping point Pi is set at an entrance of the specific section X. At the stopping point Pi, the transport vehicle V stops in response to the stop command Ss issued by the section control system C. A passing point Po is set at an exit of the specific section X. The transport vehicle V that has received the passing permission Sp from the section control system C passes through the passing point Po. The stopping point Pi and the passing point Po are each defined, for example, by a one‑dimensional code, a two‑dimensional code, an IC tag, or the like, and store address information representing the locations at which they are installed.

The transport vehicle V makes a passing permission request to the section control system C in order to be allowed to pass through the specific section X.

If, as shown in FIG. 2A, there is a conflict between passing permission requests from a plurality of transport vehicles V, the section control system C grants the passing permission Sp only to one of the transport vehicles V and issues the stop command Ss to the other transport vehicle V.

The transport vehicle V that has been granted the passing permission Sp passes through the specific section X. The transport vehicle V that has not been granted the passing permission Sp stops at the stopping point Pi and waits at the stopping point Pi until it is granted the passing permission Sp by the section control system C.

As shown in FIG. 2B, after the transport vehicle V that was granted the passing permission Sp has exited the specific section X, the section control system C performs occupancy cancellation processing Sr to cancel the occupancy of the passing point Po that has been occupied for this transport vehicle V. As a result, the section control system C becomes able to occupy the passing point Po for another transport vehicle V.

Specifically, the transport vehicle V passes through the specific section X based on the procedure shown in FIG. 3.

That is, as shown in FIG. 3, the transport vehicle V makes a passing permission request to the section control system C in order to be allowed to pass through the specific section X, either before reaching the stopping point Pi (entrance) or at the stopping point Pi (#11).

If the section control system C determines that it is permissible to grant the passing permission Sp to the transport vehicle V that has made the passing permission request, the section control system C performs occupancy processing for occupy the passing point Po (exit) for this transport vehicle V (#12). In this occupancy processing, for example, the section control system C registers the passing point Po under a unique name (identification number, etc.) of the transport vehicle V. After executing the occupancy processing, the section control system C grants the passing permission Sp to the transport vehicle V (#13).

Note that the section control system C determines whether to grant the passing permission Sp to the transport vehicle V based on whether the passing point Po for which the passing permission request has been made is already occupied. If the passing point Po is already occupied by another transport vehicle V, the section control system C does not grant the passing permission Sp. Conversely, if the passing point Po is not occupied, the section control system C grants the passing permission Sp.

The transport vehicle V that has been granted the passing permission Sp passes the passing point Po (#14), and thereafter transmits, to the section control system C, a passing completion notification indicating that the transport vehicle V has passed the passing point Po (#15).

Upon receiving the passing completion notification from the transport vehicle V, the section control system C performs occupancy cancellation processing for cancelling the occupancy of the passing point Po (#16). In this occupancy cancellation processing, for example, the section control system C deletes the registration of the transport vehicle V at the passing point Po. The occupancy cancellation processing makes the passing point Po unoccupied, and enables the section control system C to accept the next transport vehicle V at the passing point Po.

That is, in the above-described comparative example, the occupancy of the passing point Po for a transport vehicle V is canceled only after this transport vehicle V has exited the specific section X. Therefore, the following transport vehicle V needs to wait until the preceding transport vehicle V exits the specific section X.

Next, the control in the specific section X according to the present disclosure will be described with reference to FIGS. 4 and 5. Note that the stopping point Pi is set at the entrance of the specific section X and the passing point Po is set at the exit, as in the comparative example. Also, the section control system C performs occupancy processing and occupancy cancellation processing for the passing point Po, as in the comparative example. That is, the section control system C is configured to execute occupancy processing for occupying the passing point Po for a transport vehicle V that is about to pass through the specific section X, and occupancy cancellation processing Sr for canceling the occupancy for another transport vehicle V that is about to pass through the specific section X.

Here, in the transport facility 100 according to the present disclosure, a cancellation point Pr that varies in accordance with predetermined conditions is set upstream of the passing point Po subjected to occupancy. The cancellation point Pr is set based on a separation distance Dr from the passing point Po. Details of the setting of the cancellation point Pr will be described later.

As shown in FIG. 4, the occupancy cancellation processing Sr executed in the transport facility 100 according to the present disclosure is processing for canceling the occupancy of the passing point Po if the transport vehicle V that has been granted the passing permission Sp for this passing point Po is located at the cancellation point Pr set upstream of the passing point Po. That is, the occupancy cancellation processing Sr for the passing point Po is performed before the transport vehicle V that has been granted the passing permission Sp for the passing point Po exits the specific section X. As a result, the section control system C becomes able to occupy the passing point Po for another transport vehicle V.

Specifically, the transport vehicle V passes through the specific section X based on the procedure shown in FIG. 5.

That is, as shown in FIG. 5, the transport vehicle V makes a passing permission request to the section control system C in order to be allowed to pass through the specific section X, either before reaching the stopping point Pi (entrance) or at the stopping point Pi (#21).

If the section control system C determines that it is permissible to grant the passing permission Sp to the transport vehicle V that has made the passing permission request, the section control system C performs occupancy processing for occupying the passing point Po (exit) for this transport vehicle V (#22). In this occupancy processing, for example, the section control system C registers the passing point Po under a unique name (identification number, etc.) of the transport vehicle V. Thereafter, the section control system C grants the passing permission Sp to the transport vehicle V (#23).

Here, as described above, the cancellation point Pr is set upstream of the passing point Po (exit) that the transport vehicle V is about to pass. After passing the cancellation point Pr (#24), the transport vehicle V issues a passing completion notification indicating that it has passed the cancellation point Pr (#25). The section control system C that has received the passing completion notification performs occupancy cancellation processing for cancelling the occupancy of the passing point Po (#26). Here, the section control system C is capable of acquiring cancellation point passing information indicating that the transport vehicle V has passed the cancellation point Pr. The section control system C performs occupancy cancellation processing for cancelling the occupancy of the passing point Po in response to acquiring the cancellation point passing information (#26). As described above, in this example, the transport vehicle V issues a passing completion notification for the cancellation point Pr upon passing the cancellation point Pr (#25), and the section control system C acquires the cancellation point passing information by receiving the passing completion notification. The transport vehicle V calculates the cancellation point Pr based on its own current position information and travel speed information, and issues the passing completion notification for the cancellation point Pr in response to the transport vehicle V reaching the cancellation point Pr. For example, the transport vehicle V measures the distance traveled from the stopping point Pi using a distance sensor such as an encoder, and determines, based on the measurement result, whether the transport vehicle V has reached the cancellation point Pr. Note that the determination of whether the transport vehicle V has reached the cancellation point Pr can also be performed by the section control system C. In this case, the transport vehicle V may periodically transmit at least either its own current position information or travel speed information to the section control system C, or transmit such information at the time when another following transport vehicle V makes a passing permission request for the specific section X. The section control system C may calculate the cancellation point Pr based on the above information obtained from the transport vehicle V. Note that in the occupancy cancellation processing, for example, the section control system C deletes the registration of the transport vehicle V at the passing point Po. The occupancy cancellation processing makes the passing point Po unoccupied, and the section control system C becomes able to accept the next transport vehicle V at the passing point Po.

Note that the transport vehicle V after passing the cancellation point Pr further continues traveling and passes the passing point Po (#27). Thereafter, the transport vehicle V issues a passing completion notification indicating that it has passed the passing point Po to the section control system C (#28).

As described above, in the transport facility 100 according to the present disclosure, the cancellation point Pr serving as a reference for the timing of canceling the occupancy of the passing point Po is set at a position upstream of the passing point Po, which is the exit of the specific section X. The section control system C then performs the occupancy cancellation processing Sr for the passing point Po if the transport vehicle V is located at the cancellation point Pr. In other words, the section control system C cancels the occupancy of the passing point Po that has been occupied for the transport vehicle V while the transport vehicle V that has been granted the passing permission Sp is present in the specific section X. Thus, the section control system C becomes able to grant a passing permission Sp for the specific section X to the following transport vehicle V even while the preceding transport vehicle V is present in the specific section X. Accordingly, the waiting time of the following transport vehicle V at the entry point of the specific section X can be shortened, allowing the following transport vehicle V to enter the specific section X at an earlier timing.

Next, the setting of the cancellation point Pr will be described.

As described above, the section control system C is configured to acquire transport vehicle information, which is information of the transport vehicle V, from the transport vehicle V. The transport vehicle V is configured to transmit its own transport vehicle information to the section control system C repeatedly at regular intervals, or at predetermined locations on the travel path 9. The cancellation point Pr is set based on the transport vehicle information of the transport vehicle V that has been granted a passing permission Sp.

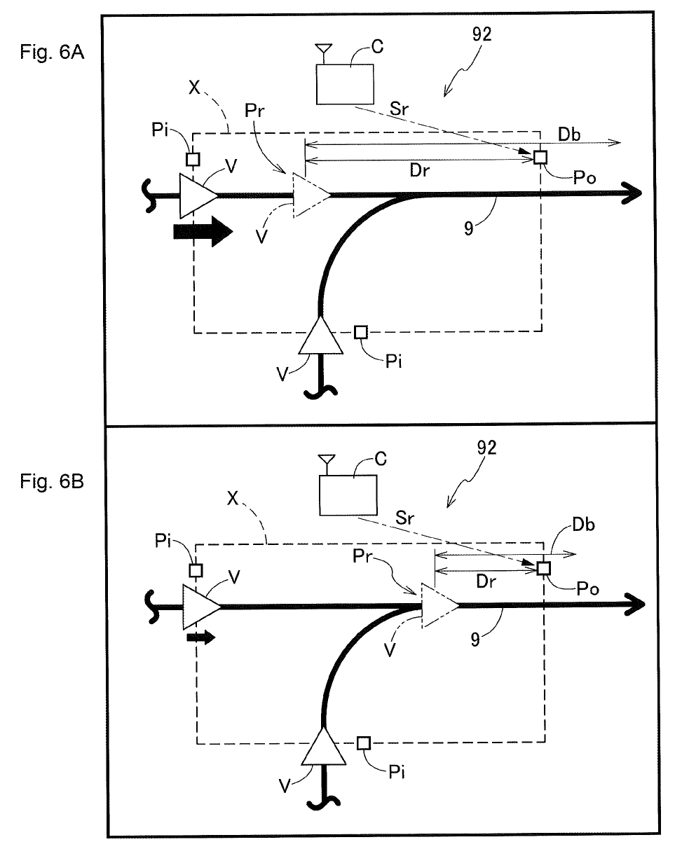

As shown in FIGS. 6A and 6B, the cancellation point Pr is set such that the separation distance Dr from the passing point Po becomes longer as the travel speed of the transport vehicle V granted the passing permission Sp increases. That is, in the present embodiment, the transport vehicle information includes travel speed information, and the cancellation point Pr is set based on the travel speed information of the transport vehicle V that has been granted the passing permission Sp.

In the present embodiment, the separation distance Dr between the cancellation point Pr and the passing point Po is set based on the travel speed of the transport vehicle V at the entrance (stopping point Pi) of the specific section X, i.e., based on the entry speed at which the transport vehicle V enters the specific section X.

FIG. 6A illustrates an example in which the transport vehicle V is granted the passing permission Sp before entering the specific section X and enters the specific section X without stopping at the stopping point Pi. FIG. 6B illustrates an example in which the transport vehicle V temporarily stops at the entrance (stopping point Pi) of the specific section X and thereafter starts proceeding after being granted the passing permission Sp.

In the case of FIG. 6A, since the travel speed (entry speed) of the transport vehicle V at the entrance (stopping point Pi) of the specific section X is relatively high, the separation distance Dr between the cancellation point Pr and the passing point Po is set relatively long. In other words, in the case where the transport vehicle V enters the specific section X without stopping at the stopping point Pi, the separation distance Dr between the cancellation point Pr and the passing point Po is set longer than in the case where the transport vehicle V enters the specific section X after temporarily stopping at the entrance (stopping point Pi) of the specific section X.

On the other hand, in the case of FIG. 6B, since the travel speed (entry speed) of the transport vehicle V at the entrance (stopping point Pi) of the specific section X is relatively low, the separation distance Dr between the cancellation point Pr and the passing point Po is set relatively short. In other words, in the case where the transport vehicle V enters the specific section X after temporarily stopping at the entrance (stopping point Pi) of the specific section X, the separation distance Dr between the cancellation point Pr and the passing point Po is set shorter than in the case where the transport vehicle V enters the specific section X without stopping at the stopping point Pi.

For example, a prediction point for predicting the travel speed of the transport vehicle V may be set downstream of the stopping point Pi, and the cancellation point Pr may be set based on a predicted value of the travel speed at the prediction point. In the case where the transport vehicle V enters the specific section X without stopping at the stopping point Pi, the predicted value of the travel speed is relatively high, and the cancellation point Pr is set such that the separation distance Dr becomes relatively long. On the other hand, in the case where the transport vehicle V enters the specific section X after temporarily stopping at the stopping point Pi, the predicted value of the travel speed is relatively low, and the cancellation point Pr is set such that the separation distance Dr becomes relatively short.

A braking distance Db of the transport vehicle V becomes longer as the travel speed increases. Thus, as a result of adopting the above configuration, even if the preceding transport vehicle V begins a stopping operation after passing the cancellation point Pr, the preceding transport vehicle V is likely to pass the passing point Po. Therefore, even if the preceding transport vehicle V begins a stopping operation before the passing point Po, the preceding transport vehicle V passes beyond the passing point Po, and the following transport vehicle V that has been granted the passing permission Sp for the same passing point Po can also pass the passing point Po. Accordingly, the following transport vehicle V can travel without stopping in the specific section X. That is, the cancellation point Pr is set such that the separation distance Dr from the passing point Po is smaller than the braking distance Db of the transport vehicle V that has been granted the passing permission Sp.

Here, the braking distance Db of the transport vehicle V depends not only on the travel speed but also on the weight of the transport vehicle V. That is, even at the same travel speed, the braking distance Db becomes longer as the weight increases. In the present embodiment, the cancellation point Pr is set such that the separation distance Dr from the passing point Po becomes longer as the weight of the transport vehicle V that has been granted the passing permission Sp increases. That is, in the present embodiment, the transport vehicle information includes weight information of the transport vehicle V, and the cancellation point Pr is set based on the weight information of the transport vehicle V that has been granted the passing permission Sp.

Furthermore, the weight of the transport vehicle V varies depending on whether the transport vehicle V is holding an article. Naturally, while the transport vehicle V is holding an article, the weight of the transport vehicle V is greater than while it is not holding an article. In the present embodiment, the cancellation point Pr is set such that the separation distance Dr from the passing point Po is longer while the transport vehicle V granted the passing permission Sp is holding an article than while it is not holding an article. That is, in the present embodiment, the transport vehicle information includes information indicating whether the transport vehicle V is holding an article (article presence information), and the cancellation point Pr is set based on the article presence information of the transport vehicle V that has been granted the passing permission Sp.

Further, the braking distance Db depends not only on the travel speed and weight but also on the wear level of the wheels of the transport vehicle V. That is, even if the other conditions are the same, the braking distance Db becomes longer as the wear level increases. In the present embodiment, the cancellation point Pr is set such that the separation distance Dr from the passing point Po becomes longer as the wear level of the wheels of the transport vehicle V granted the passing permission Sp increases. That is, in the present embodiment, the transport vehicle information includes wear level information of the wheels of the transport vehicle V, and the cancellation point Pr is set based on the wear level information of the transport vehicle V that has been granted the passing permission Sp. Note that the wear level may be calculated based on direct indicators such as a wheel thickness detected by a camera sensor or the like, or may be calculated based on indirect indicators such as a continuous usage time of the wheels.

In the above description, a simple specific section X that includes only one merging area 92 has been illustrated to describe the control in the specific section X. However, the specific section X may also include more complex layouts as shown in FIGS. 7 and 8. The above-described control in the specific section X is also applied to the specific section X having the layouts shown in FIGS. 7 and 8.

That is, as shown in FIG. 7, the specific section X may include more than one branching area 91 and more than one merging area 92. In the example shown in FIG. 7, the stopping points Pi include a first stopping point Pi1 and a second stopping point Pi2, each corresponding to a different entrance to the specific section X. The passing points Po include a first passing point Po1 and a second passing point Po2, each corresponding to a different exit from the specific section X. Each of the first passing point Po1 and the second passing point Po2 is disposed on the downstream side of both the first stopping point Pi1 and the second stopping point Pi2 on the travel path 9. FIG. 7 illustrates a preceding transport vehicle V that enters the specific section X earlier (hereinafter referred to as “preceding transport vehicle A”) and a following transport vehicle V that enters the specific section X later (hereinafter referred to as “following transport vehicle B”).

In this type of layout, a transport vehicle V that has entered the specific section X may select the first passing point Po1 or the second passing point Po2 as an exit. However, even if a preceding transport vehicle A and a following transport vehicle B select different exits (passing points Po), the entry of both into the specific section X is not permitted unconditionally. If this is permitted, it is possible that the following transport vehicle B, which travels along the same path as the preceding transport vehicle A up to a certain point, will collide with the preceding transport vehicle A on the upstream side of the branching area 91.

In view of this, the section control system C is configured to, in the case of granting the passing permission Sp for the first passing point Po1 or the second passing point Po2 in the occupancy processing for occupying a passing point Po, occupy both the first passing point Po1 and the second passing point Po2 for a transport vehicle V that has requested that passing permission Sp. With this, for example, even when the preceding transport vehicle A is scheduled to pass the first passing point Po1 and the following transport vehicle B is scheduled to pass the second passing point Po2, both the first passing point Po1 and the second passing point Po2 are occupied for the preceding transport vehicle A. Thus, the entry of the following transport vehicle B into the specific section X is rejected, and the following transport vehicle B waits at the stopping point Pi. However, if this rule is followed too strictly, the waiting time of the following transport vehicle B will increase, and the transport efficiency of the entire facility may decrease. Therefore, even in this type of layout, the cancellation point Pr is set upstream of the passing point Po. If the preceding transport vehicle A is located at the cancellation point Pr, the occupancy cancellation processing Sr is executed for the passing point Po even before the preceding transport vehicle A passes the passing point Po. As a result, the passing point Po becomes available for occupancy for the following transport vehicle B.

In the present embodiment, if, after the section control system C grants the passing permission Sp for either the first passing point Po1 or the second passing point Po2 to the preceding transport vehicle A that has entered the specific section X earlier, the section control system C receives a request for the passing permission Sp for either the first passing point Po1 or the second passing point Po2 from the following transport vehicle B that enters the specific section X after the preceding transport vehicle A as shown in FIG. 7, the section control system C executes occupancy cancellation processing on the condition that the passing point Po that the preceding transport vehicle A is scheduled to pass (the first passing point Po1 in the illustrated example) and the passing point Po that the following transport vehicle B is scheduled to pass (the second passing point Po2 in the illustrated example) are different.

Also, as shown in FIG. 8, there are cases where the preceding transport vehicle A and the following transport vehicle B are scheduled to pass the same passing point Po (the first passing point Po1 in the illustrated example). Even in such cases, the section control system C executes the occupancy cancellation processing on the condition that the passing point Po that the preceding transport vehicle A is scheduled to pass and the passing point Po that the following transport vehicle B is scheduled to pass are the same.

FIG. 7 illustrates a case where the preceding transport vehicle A and the following transport vehicle B are scheduled to pass different passing points Po, while FIG. 8 illustrates a case where the preceding transport vehicle A and the following transport vehicle B are scheduled to pass the same passing point Po.

Here, the setting position of the cancellation point Pr may be changed depending on whether the respective passing points Po that the preceding transport vehicle A and the following transport vehicle B are scheduled to pass are different or the same. For example, if the passing points Po that the preceding transport vehicle A and the following transport vehicle B are scheduled to pass are the same (the case in FIG. 8), the following transport vehicle B is to travel along the same travel path 9 as the preceding transport vehicle A, and collision with the preceding transport vehicle A is more likely than if the passing points Po that those transport vehicles are scheduled to pass are different (the case in FIG. 7). For this reason, if the passing points Po that the preceding transport vehicle A and the following transport vehicle B are scheduled to pass are the same, the cancellation point Pr is set such that the separation distance Dr from the passing point Po becomes shorter than if those passing points Po are different. The cancellation point Pr is thereby set at a position closer to the passing point Po, and the entry of the following transport vehicle B into the specific section X is delayed. This can reduce the likelihood of a collision with the preceding transport vehicle A.

### Other Embodiments

Next, other embodiments will be described.
(1) In the above embodiment, an example has been described in which the zone controller serving as the section control system C performs the occupancy cancellation processing Sr for the passing point Po. However, such an example is not limiting. The section control system C may include a host controller or a transport vehicle controller mounted on the transport vehicle V, and therefore the occupancy cancellation processing Sr for the passing point Po may be performed by the host controller or the transport vehicle controller.
(2) In the above embodiment, an example has been described in which the section control system C acquires cancellation point passing information by receiving a passing completion notification from the transport vehicle V indicating that it has passed the cancellation point Pr, and thereafter performs the occupancy cancellation processing. However, such an example is not limiting. For example, the section control system C may be configured to monitor the position of the transport vehicle V using a sensor such as a camera, and acquire cancellation point passing information by acquiring the detection results from the sensor when the transport vehicle V passes the cancellation point Pr.
(3) In the above embodiment, an example has been described in which the transport vehicle V measures the distance traveled from the stopping point Pi using a distance sensor such as an encoder and determines whether it has reached the cancellation point Pr based on the measurement results. However, such an example is not limiting. A configuration may be adopted in which an information storage medium such as a one‑dimensional code or a two‑dimensional code storing information regarding the cancellation point Pr is provided on the travel path 9, and the transport vehicle V reads this information to grasp the position of the cancellation point Pr.
(4) In the above embodiment, an overhead hoist transport vehicle has been described as an example of the transport vehicle V. However, such an example is not limiting. The transport vehicle V may alternatively be a floor‑traveling vehicle that travels on the floor surface. In this case, the travel path 9 may be set by rails, magnetic tape, or the like.
(5) Note that the configurations disclosed in the above embodiment can also be applied in combination with the configurations disclosed in the other embodiments as long as no contradiction arises. Regarding the other configurations as well, the embodiments disclosed in the present specification are in all respects merely examples. Accordingly, it is possible to make various changes as appropriate without departing from the gist of the present disclosure.

### Summary of the Present Embodiment

A summary of the present embodiment will be described below.

A transport facility includes:
a transport vehicle;
a travel path along which the transport vehicle is travelable; and
a section control system configured to issue a passing permission and a stop command to the transport vehicle traveling in a specific section set on the travel path to control the transport vehicle,
the specific section including at least one stopping point set at an entrance thereof, wherein the transport vehicle is configured to stop at the stopping point in response to the stop command,
the specific section including at least one passing point set at an exit thereof, wherein the transport vehicle that has been granted the passing permission is configured to pass the passing point,
the section control system being configured to execute: (i) occupancy processing for occupying the passing point for the transport vehicle that is about to pass through the specific section; and (ii) occupancy cancellation processing for canceling the occupancy for another transport vehicle that is about to pass through the specific section,
the specific section including a cancellation point that is set upstream of the passing point subjected to occupancy and that is variable in accordance with a predetermined condition,
the occupancy cancellation processing being processing for canceling the occupancy of the passing point if the transport vehicle that has been granted the passing permission for the passing point is located at the cancellation point set upstream of the passing point, and
the cancellation point being set in such a manner that a separation distance from the passing point becomes longer as a travel speed of the transport vehicle that has been granted the passing permission increases.

According to this configuration, the occupancy of the passing point that has been occupied for a preceding transport vehicle can be canceled earlier for a following transport vehicle. This makes it possible to shorten the waiting time of the following transport vehicle at the stopping point, allowing the following transport vehicle to enter the specific section earlier. In addition, the cancellation point serving as a trigger for occupancy cancellation is set in accordance with the travel speed of the transport vehicle. Since the braking distance of the transport vehicle becomes longer as the travel speed increases, this configuration can make it difficult for the preceding transport vehicle to stop before reaching the passing point, even if the preceding transport vehicle begins a stopping operation after passing the cancellation point. Therefore, it is possible to reduce the likelihood that the following transport vehicle that has been granted a passing permission for the passing point will stop in the specific section in order to avoid a collision with the stopped preceding transport vehicle. As described above, according to this configuration, the movement of the transport vehicles in the specific section can be facilitated, and the transport efficiency of the entire facility can be improved.

Preferably, the cancellation point is set in such a manner that the separation distance from the passing point is smaller than a braking distance of the transport vehicle that has been granted the passing permission.

According to this configuration, even if the preceding transport vehicle begins a stopping operation at the cancellation point, the preceding transport vehicle will pass the passing point before completing the braking distance. Therefore, it is possible to reduce the likelihood that the following transport vehicle that has been granted a passing permission for the passing point will stop in the specific section in order to avoid a collision with the stopped preceding transport vehicle.

Preferably, the cancellation point is set in such a manner that the separation distance from the passing point becomes longer as a weight of the transport vehicle that has been granted the passing permission increases.

According to this configuration, the cancellation point serving as a trigger for occupancy cancellation is set in accordance with the weight of the transport vehicle. Therefore, even in the case where the braking distance of the transport vehicle varies due to the weight of the transport vehicle, this configuration can make it difficult for the transport vehicle to stop before reaching the passing point. Therefore, it is possible to reduce the likelihood that the following transport vehicle that has been granted a passing permission for the passing point will stop in the specific section in order to avoid a collision with the stopped preceding transport vehicle.

Preferably, the at least one stopping point includes a first stopping point and a second stopping point, each corresponding to a different entrance to the specific section,
the at least one passing point includes a first passing point and a second passing point, each corresponding to a different exit from the specific section,
each of the first passing point and the second passing point is disposed on a downstream side of both the first stopping point and the second stopping point on the travel path,
the section control system is configured to, in a case of granting the passing permission for the first passing point or the second passing point in the occupancy processing, occupy both the first passing point and the second passing point for the transport vehicle that has requested the passing permission, and
if, after the section control system has granted the passing permission for the first passing point or the second passing point to a preceding transport vehicle being the transport vehicle that has entered the specific section earlier, the section control system receives a request for the passing permission for the first passing point or the second passing point from a following transport vehicle being another transport vehicle that enters the specific section after the preceding transport vehicle, the section control system executes the occupancy cancellation processing on a condition that the passing point that the preceding transport vehicle is scheduled to pass and the passing point that the following transport vehicle is scheduled to pass are different.

According to this configuration, since the passing points that the preceding transport vehicle and the following transport vehicle are scheduled to pass are different, it is possible to grant a passing permission to the following transport vehicle early, while reducing the likelihood that the following transport vehicle will stop in the specific section in order to avoid a collision with the preceding transport vehicle.

### Industrial Applicability

The technology according to the present disclosure can be utilized in a transport facility that includes a transport vehicle, a travel path along which the transport vehicle is travelable, and a section control system configured to issue a passing permission and a stop command to the transport vehicle traveling in a specific section set on the travel path to control the transport vehicle.

What is claimed is:

1. A transport facility comprising:
a transport vehicle;
a travel path along which the transport vehicle is travelable; and
a section control system configured to issue a passing permission and a stop command to the transport vehicle traveling in a specific section set on the travel path to control the transport vehicle, and
wherein:
the specific section comprises at least one stopping point set at an entrance thereof, wherein the transport vehicle is configured to stop at the stopping point in response to the stop command,
the specific section comprises at least one passing point set at an exit thereof, wherein the transport vehicle that has been granted the passing permission is configured to pass the passing point,
the section control system is configured to execute: (i) occupancy processing for occupying the passing point for the transport vehicle that is about to pass through the specific section; and (ii) occupancy cancellation processing for canceling the occupancy for another transport vehicle that is about to pass through the specific section,
the specific section comprises a cancellation point that is set upstream of the passing point subjected to occupancy and that is variable in accordance with a predetermined condition,
the occupancy cancellation processing is processing for canceling the occupancy of the passing point if the transport vehicle that has been granted the passing permission for the passing point is located at the cancellation point set upstream of the passing point, and
the cancellation point is set in such a manner that a separation distance from the passing point becomes longer as a travel speed of the transport vehicle that has been granted the passing permission increases.

2. The transport facility according to claim 1,
wherein the cancellation point is set in such a manner that the separation distance from the passing point is smaller than a braking distance of the transport vehicle that has been granted the passing permission.

3. The transport facility according to claim 1,
wherein the cancellation point is set in such a manner that the separation distance from the passing point becomes longer as a weight of the transport vehicle that has been granted the passing permission increases.

4. The transport facility according to claim 1, wherein:
the at least one stopping point comprises a first stopping point and a second stopping point, each corresponding to a different entrance to the specific section,
the at least one passing point comprises a first passing point and a second passing point, each corresponding to a different exit from the specific section,
each of the first passing point and the second passing point is disposed on a downstream side of both the first stopping point and the second stopping point on the travel path,
the section control system is configured to, in a case of granting the passing permission for the first passing point or the second passing point in the occupancy processing, occupy both the first passing point and the second passing point for the transport vehicle that has requested the passing permission, and
if, after the section control system has granted the passing permission for the first passing point or the second passing point to a preceding transport vehicle being the transport vehicle that has entered the specific section earlier, the section control system receives a request for the passing permission for the first passing point or the second passing point from a following transport vehicle being another transport vehicle that enters the specific section after the preceding transport vehicle, the section control system executes the occupancy cancellation processing on a condition that the passing point that the preceding transport vehicle is scheduled to pass and the passing point that the following transport vehicle is scheduled to pass are different.
